(19) United States
(12) Patent Application Publication
(10) Pub. No.: US 2019/0022549 A1
(43) Pub. Date: Jan. 24, 2019

(54) SEMICONDUCTOR CHILLING MULTILAYER COMBINED BUFFER SOLAR POWERED PHOTOVOLTAIC DISTILLER

(71) Applicant: Kai Lok LAM, Hong Kong (HK)

(72) Inventor: Kai Lok LAM, Hong Kong (HK)

(21) Appl. No.: 15/692,081

(22) Filed: Aug. 31, 2017

(30) Foreign Application Priority Data
Jul. 20, 2017 (CN) 201710597724.2

(51) Int. Cl. B01D 3/00; B01D 1/00; C02F 1/14; C02F 1/18; F24J 2/08; F24J 2/26; F24J 2/32; F24J 2/44; F24J 2/46; F24J 2/34; H01L 31/052; H02S 40/44

(52) U.S. Cl. CPC B01D 3/00; B01D 1/0035; C02F 1/14; C02F 1/18; F24J 2/08; H02S 40/44; F24J 2/32; F24J 2/44; F24J 2/462; F24J 2/345; H01L 31/0521; F24J 2/265

(57) ABSTRACT

The present invention relates to a semiconductor chilling multilayer combined buffer solar powered photovoltaic distiller, comprises a machine frame, a first water tank for storing water to be distilled, a water pump, a heat collector, a steam pump, a condensation pipe, a second water tank for storing desalinated water, a PLC controller and a solar panel. The heat collector comprises an outer glass case and an inner glass case. The first water tank is connected to one end of the chamber of the inner glass case. The other end of the inner glass case is connected to the buffer tank. The steam pump is connected to the buffer tank. The steam pump, the condensation pipe fixedly mounted on the support plate and the water tank fixedly mounted on the base plate are connected in series. A semiconductor chilling plate and an electric heater are alternately disposed between the condensation pipe and the support plate. The structure is reasonable, having the advantages of simple, convenient to use, high energy utilization rate, does not rely on external power supply etc. can effectively solve the problem of traditional water resource treatment having big energy consumption, and the equipment and site being not movable.

### FIELD OF INVENTION

The present invention relates to the field of water resource distillation and desalination devices, in particular to a semiconductor chilling multilayer combined buffer solar powered photovoltaic distiller.

### BACKGROUND OF INVENTION

As world population is rapidly increasing and caused by pollution due to heavy exploitation and utilization of resources, the problem with shortage of water is as serious as ever. Among the water resources of the earth, 97.5% is not drinkable, therefore a key question for solving the shortage of drinkable water is how to convert undrinkable water resource into drinkable water resource. Traditional treatment methods include distillation, ion exchange, dialysis, reverse osmosis, or freezing, but all such methods need to consume a lot of fossil fuel or electrical energy, and treatment site and devices are fixed and not portable, and extra water pipes are needed for transporting treated water. Not only the cost of treatment is high, consumption of fossil fuel energy also causes environmental pollution, and the environmental pollution in turn causes shortage of drinkable water. For undeveloped regions, it is impossible to maintain a big energy consumption. Therefore a water resource treatment device that does not rely external power supply and easily portable is needed.

### SUMMARY OF INVENTION

The technical problem to be solved by the present invention is: to overcome the aforementioned problem, a semiconductor chilling multilayer combined buffer solar powered photovoltaic distiller is provided. The structure is reasonable, having the advantages of simple, convenient to use, high energy utilization rate, does not rely on external power supply etc. can effectively solve the problem of traditional water resource treatment having big energy consumption, and the equipment and site being not movable.

The technical solution used in the present invention to solve the technical problem is: a semiconductor chilling multilayer combined buffer solar powered photovoltaic distiller, comprises a machine frame, a first water tank for storing water to be distilled, a water pump, a heat collector, a steam pump, a condensation pipe, a second water tank for storing desalinated water, a PLC controller and a solar panel. The machine frame comprises a base plate, a support plate and a support pole. The two ends of the support plate are hinged to the base plate and the support pole respectively. An adjustment plate having a plurality of grooves is fixedly mounted on the base plate, a free end of the support pole is abut against the groove.

The heat collector is fixedly mounted on the support plate. The heat collector comprises an outer glass case and an inner glass case having a rectangular hollow structure, the inner glass case is sleeved to the outer class case, an inner wall of the outer glass case comprises a protrusion that abuts against the inner glass case, a vacuum chamber is further disposed between the inner glass case and the outer glass case. The first water tank is fixedly mounted on the base plate, the first water tank is connected to one end of the chamber of the inner glass case through the water pump and a one way valve. The other end of the inner glass case is connected to the buffer tank for collecting steam.

The steam pump is connected to the buffer tank. The steam pump, the condensation pipe fixedly mounted on the support plate and the water tank fixedly mounted on the base plate are connected in series. A semiconductor chilling plate and an electric heater are alternately disposed between the condensation pipe and the support plate. The solar panel is disposed on the support plate, the solar panel is electrically connected to a battery fixedly mounted on the support plate. The PLC controller is electrically connected to the battery, the water pump and the steam pump.

The buffer tank is made of transparent glass, a number of ultraviolet sterilization lamps and a protector shield for protecting the ultraviolet sterilization lamps are disposed on the buffer tank.

In a preferred embodiment, a number of casters are disposed on the base plate.

In a preferred embodiment, the protrusion is in one piece with the outer glass case.

In a preferred embodiment, a float level switch is disposed inside the chamber of the inner glass case.

In a preferred embodiment, a filter is disposed at an input of the first water tank.

In a preferred embodiment, a light sensor is disposed on the support plate, the light sensor is electrically connected to the PLC controller.

In a preferred embodiment, the ultraviolet sterilization lamps are electrically connected to the battery.

The advantage of the present invention is: the semiconductor chilling multilayer combined buffer solar powered photovoltaic distiller of the present invention, uses solar power to heat and vaporize water, steam then condenses into drinkable water, the steam is ultraviolet sterilized when flowing through the buffer tank to enhance safety. The semiconductor chilling plate disposed between the condensation pipe and the heat collector provides good condensation results, and guides the heat to the heat collector, increasing energy utilization rate. The heat collector is made of two layers of glass cases, with a vacuum chamber in between the two layers of glass cases, providing good thermal insulation. On the other hand, using the solar panel to convert solar power into electrical energy to drive the operation of the equipment, does not need to rely on external power supply, the structure is simple and compact, is convenient for transport. The structure is reasonable, having the advantages of simple, convenient to use, high energy utilization rate, does not rely on external power supply etc. can effectively solve the problem of traditional water resource treatment having big energy consumption, and the equipment and site being not movable.

### BRIEF DESCRIPTION OF DRAWINGS

The present invention is further explained below with the accompanying drawings and embodiments.

FIG. 1 is a side structural schematic diagram of a semiconductor chilling multilayer combined buffer solar powered photovoltaic distiller according to the present invention.

FIG. 2 is a front structural schematic diagram of a semiconductor chilling multilayer combined buffer solar powered photovoltaic distiller according to the present invention.

FIG. 3 is a structural schematic diagram of a heat collector of a semiconductor chilling multilayer combined buffer solar powered photovoltaic distiller according to the present invention.

FIG. 4 is a structural schematic diagram of a buffer tank of a semiconductor chilling multilayer combined buffer solar powered photovoltaic distiller according to the present invention.

Reference numbers in the drawings: 1 machine frame, 11 base plate, 12 support plate, 13 support pole, 14 adjustment plate, 15 caster, 16 groove, 2 first water tank, 21 filter, 3 water pump, 4 heat collector, 41 one way valve, 42 floating ball level switch, 44 outer glass case, 45 inner glass case, 46 vacuum chamber, 47 protrusion, 48 buffer tank, 481 protector shield, 482 ultraviolet sterilization lamp, 5 steam pump, 6 condensation pipe, 61 semiconductor chilling plate, 62 electric heater, 7 second water tank, 8 PLC controller, 9 solar panel, 91 battery, 92 light sensor.

### DETAILED DESCRIPTION OF INVENTION

The present invention is further explained below along with the accompanying drawings. The drawings are all simplified schematic diagrams which only illustrates the basic structure of the present invention, as such only the components material to the present invention are shown.

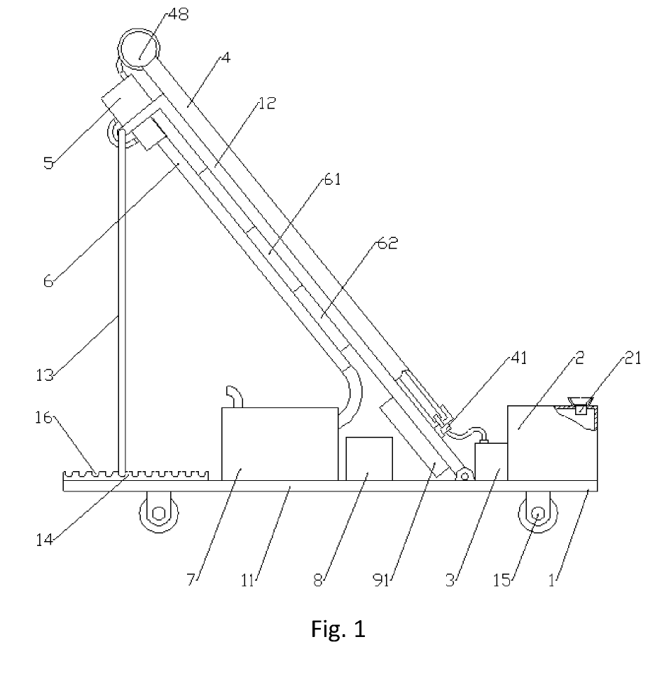

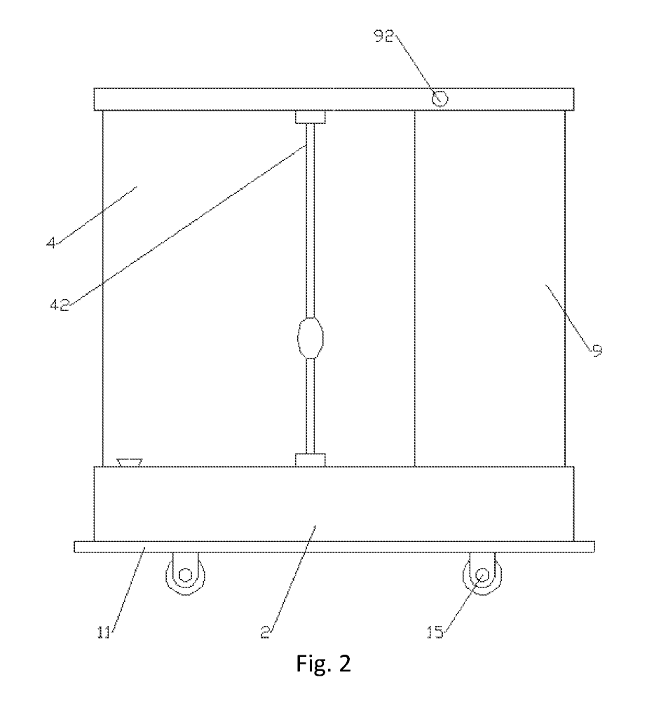

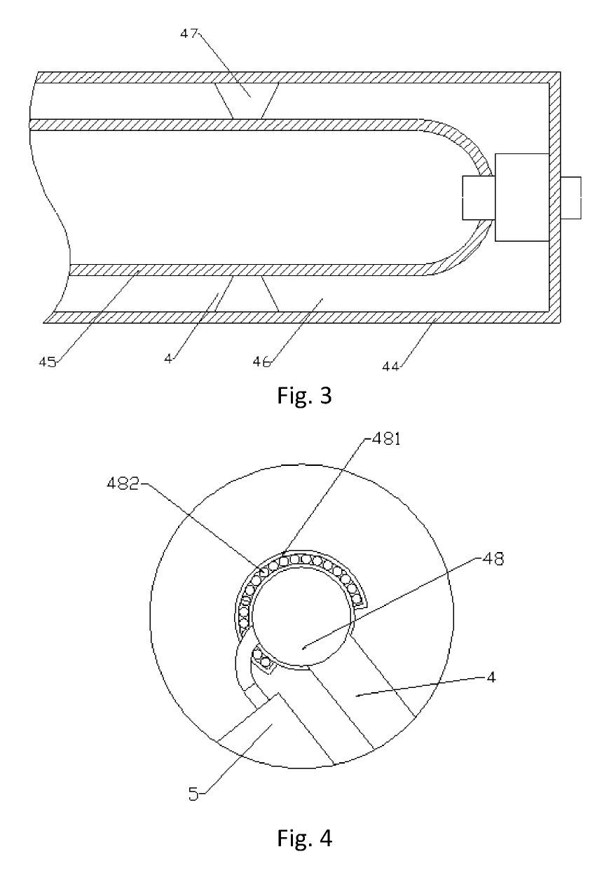

A semiconductor chilling multilayer combined buffer solar powered photovoltaic distiller is shown in FIGS. 1-4. The distiller comprises a machine frame 1, a first water tank 2 for storing water to be distilled, a water pump 3, a heat collector 4, a steam pump 5, a condensation pipe 6, a second water tank 7 for storing desalinated water, a PLC controller 8 and a solar panel 9. The machine frame 1 comprises a base plate 11, a support plate 12 and a support pole 13. The two ends of the support plate 12 are hinged to the base plate 11 and the support pole 13 respectively. An adjustment plate 14 having a plurality of grooves 16 is fixedly mounted on the base plate 11, a free end of the support pole 13 is abut against the groove 16.

The heat collector 4 is fixedly mounted on the support plate 12. The heat collector 4 comprises an outer glass case 44 and an inner glass case 45 having a rectangular hollow structure, the inner glass case 45 is sleeved to the outer class case 44, an inner wall of the outer glass case 44 comprises a protrusion 47 that abuts against the inner glass case 45, a vacuum chamber 46 is further disposed between the inner glass case 45 and the outer glass case 44. The first water tank 2 is fixedly mounted on the base plate 11, the first water tank 2 is connected to one end of the chamber of the inner glass case 45 through the water pump 3 and a one way valve 41. The other end of the inner glass case 45 is connected to the buffer tank 48 for collecting steam.

The steam pump 5 is connected to the buffer tank 48. The steam pump 5, the condensation pipe 6 fixedly mounted on the support plate 12 and the water tank fixedly mounted on the base plate 11 are connected in series. A semiconductor chilling plate 61 and an electric heater 62 are alternately disposed between the condensation pipe 6 and the support plate. The solar panel 9 is disposed on the support plate 12, the solar panel 9 is electrically connected to a battery 91 fixedly mounted on the support plate 12. The PLC controller 8 is electrically connected to the battery 91, the water pump 3 and the steam pump 5.

The buffer tank 48 is made of transparent glass, a number of ultraviolet sterilization lamps 482 and a protector shield 481 for protecting the ultraviolet sterilization lamps 482 are disposed on the buffer tank 48.

A number of casters 15 are disposed on the base plate 11. The protrusion 47 is in one piece with the outer glass case 44. A float level switch 42 is disposed inside the chamber of the inner glass case 45. A filter 21 is disposed at an input of the first water tank 2. A light sensor 92 is disposed on the support plate 12, the light sensor 92 is electrically connected to the PLC controller 8. The ultraviolet sterilization lamps 482 are electrically connected to the battery 91.

The semiconductor chilling multilayer combined buffer solar powered photovoltaic distiller of the present invention, uses solar power to heat and vaporize water, steam then condenses into drinkable water, the steam is ultraviolet sterilized when flowing through the buffer tank to enhance safety. The semiconductor chilling plate disposed between the condensation pipe and the heat collector provides good condensation results, and guides the heat to the heat collector, increasing energy utilization rate. The heat collector is made of two layers of glass cases, with a vacuum chamber in between the two layers of glass cases, providing good thermal insulation. On the other hand, using the solar panel to convert solar power into electrical energy to drive the operation of the equipment, does not need to rely on external power supply, the structure is simple and compact, is convenient for transport. The structure is reasonable, having the advantages of simple, convenient to use, high energy utilization rate, does not rely on external power supply etc. can effectively solve the problem of traditional water resource treatment having big energy consumption, and the equipment and site being not movable.

As revealed by the preferred embodiments of the present invention, based on the aforementioned description, a person skilled in the art can make various modifications and adjustments without departing from the technical concept of the present invention. The technical scope of the present invention is not limited to the specification but is defined by the scope of the claims.

What is claimed is:

1. A semiconductor chilling multilayer combined buffer solar powered photovoltaic distiller, comprises a machine frame, a first water tank for storing water to be distilled, a water pump, a heat collector, a steam pump, a condensation pipe, a second water tank for storing desalinated water, a PLC controller and a solar panel; the machine frame comprises a base plate, a support plate and a support pole; the two ends of the support plate are hinged to the base plate and the support pole respectively; an adjustment plate having a plurality of grooves is fixedly mounted on the base plate, a free end of the support pole is abut against the groove;
the heat collector is fixedly mounted on the support plate; the heat collector comprises an outer glass case and an inner glass case having a rectangular hollow structure, the inner glass case is sleeved to the outer class case, an inner wall of the outer glass case comprises a protrusion that abuts against the inner glass case, a vacuum chamber is further disposed between the inner glass case and the outer glass case; the first water tank is fixedly mounted on the base plate, the first water tank is connected to one end of the chamber of the inner glass case through the water pump and a one way valve; the other end of the inner glass case is connected to the buffer tank for collecting steam;
the steam pump is connected to the buffer tank; the steam pump, the condensation pipe fixedly mounted on the support plate and the water tank fixedly mounted on the base plate are connected in series; a semiconductor chilling plate and an electric heater are alternately disposed between the condensation pipe and the support plate; the solar panel is disposed on the support plate, the solar panel is electrically connected to a battery fixedly mounted on the support plate; the PLC controller is electrically connected to the battery, the water pump and the steam pump;
the buffer tank is made of transparent glass, a number of ultraviolet sterilization lamps and a protector shield for protecting the ultraviolet sterilization lamps are disposed on the buffer tank.

2. The semiconductor chilling multilayer combined buffer solar powered photovoltaic distiller according to claim 1, characterized in that: a number of casters are disposed on the base plate.

3. The semiconductor chilling multilayer combined buffer solar powered photovoltaic distiller according to claim 1, characterized in that: the protrusion is in one piece with the outer glass case.

4. The semiconductor chilling multilayer combined buffer solar powered photovoltaic distiller according to claim 1, characterized in that: a float level switch is disposed inside the chamber of the inner glass case.

5. The semiconductor chilling multilayer combined buffer solar powered photovoltaic distiller according to claim 1, characterized in that: a filter is disposed at an input of the first water tank.

6. The semiconductor chilling multilayer combined buffer solar powered photovoltaic distiller according to claim 1, characterized in that: a light sensor is disposed on the support plate, the light sensor is electrically connected to the PLC controller.

7. The semiconductor chilling multilayer combined buffer solar powered photovoltaic distiller according to claim 1, characterized in that: the ultraviolet sterilization lamps are electrically connected to the battery.
